(19) United States
(12) Patent Application Publication
(10) Pub. No.: US 2010/0183983 A1
(43) Pub. Date: Jul. 22, 2010

(54) PROCESS FOR MANUFACTURING ELECTRONIC DEVICE

(75) Inventors: Rie Takayama, Tokyo (JP); Toyosei Takahashi, Tokyo (JP)

Correspondence Address: SMITH, GAMBRELL & RUSSELL, SUITE 3100, PROMENADE II, 1230 PEACHTREE STREET, N.E., ATLANTA, GA, 30309-3592, US

(73) Assignee: Sumitomo Bakelite Co., Ltd., Tokyo (JP)

(21) Appl. No.: 12/665,175

(22) PCT Filed: Jun. 16, 2008
(86) PCT No.: PCT/JP2008/001545

§ 371 Date: Dec. 17, 2009

(30) Foreign Application Priority Data
Jun. 19, 2007 (JP) 2007-161475

(51) Int. Cl. G03F 7/20

(52) U.S. Cl. 430/311

(57) ABSTRACT

A process of this invention contains forming a resin composition containing a filler and a photocurable resin over a substrate (a transparent substrate 13) having a mark or an electronic component (a light receiving unit 11 and a base substrate 12 on which the light receiving unit 11 is formed) having a mark such that the resin composition covers the mark; aligning a mask in an exposure machine with the substrate on which the resin composition is formed or the electronic component on which the resin composition is formed; selectively exposing the resin composition with light via the mask and then the developing the resin composition for leaving the resin composition in a predetermined region; and disposing the substrate and the electronic component such that they face each other and bonding these via the resin composition. In aligning a mask in an exposure machine with the substrate on which the resin composition is formed or the electronic component on which the resin composition is formed, the mark is detected using a light with a wavelength of 1.5 times or more of an average particle size of the filler in the resin composition.

### TECHNICAL FIELD

The present invention relates to a process for manufacturing an electronic device.

### BACKGROUND ART

Conventionally, when an electronic component is placed over a substrate, a frame-shaped material is sometimes formed between a substrate and an electronic component for ensuring a predetermined gap between the substrate and the electronic component.

For example, in a light receiving device, a frame-shaped material surrounding a light receiving unit is formed between a transparent substrate and a base substrate having the light receiving unit.

When such an electronic device is produced, a resin composition containing a photocurable resin is formed such that the composition covers the substrate or the electronic component.

Then, a predetermined region in the resin composition is exposed and developed for forming the frame-shaped material as described above.

Then, the electronic component and the substrate are placed via the frame-shaped material, facing each other (see, for example, Patent Reference 1).

Patent Reference 1: Japanese laid-open patent publication No. 2006-70053.

### Problem to be Solved by the Invention

We have, however, found that the conventional process for manufacturing an electronic device have the following problems.

As described above, when an electronic device is produced, a predetermined region in the resin composition is exposed, during which a mask for an exposure machine must be set over the resin composition.

When this mask is placed, the mask is aligned with the electronic component or the substrate with reference to a mark formed in the electronic component or the substrate, and the mark formed in the electronic component or the substrate is covered by the resin composition. It is, therefore, difficult to detect the mark formed in the electronic component or the substrate.

Thus; aligning of the mask with the electronic component or the substrate can take much time, leading to a reduced efficiency in producing an electronic device.

An objective of the present invention is to provide a process for manufacturing an electronic device, whereby a production efficiency can be improved.

### Means for Solving Problem

In accordance with the present invention, there is provided a process for manufacturing an electronic device comprising

forming a resin composition containing a filler and a photocurable resin over a substrate having a mark or an electronic component having a mark such that the resin composition covers said mark in said substrate or said mark in said electronic component,

aligning a mask of an exposure machine with said substrate on which said resin composition is formed or said electronic component on which said resin composition is formed,

selectively exposing said resin composition with light via said mask and then the developing the resin composition for leaving said resin composition in a predetermined region and

placing said substrate and said electronic component such that they face each other and bonding these via said resin composition,

wherein in said aligning a mask of an exposure machine with said substrate on which said resin composition is formed or said electronic component on which said resin composition is formed, said mark of the substrate on which said resin composition is formed or the mark of the electronic component on which said resin composition is formed is detected using a light with a wavelength of 1.5 times or more of an average particle size of said filler in said resin composition and the mask of said exposure machine is aligned with said substrate on which said resin composition is formed or said electronic component on which said resin composition is formed.

According to this invention, in aligning the mask of the exposure machine with the substrate on which said resin composition is formed or the electronic component on which said resin composition is formed, the mark is detected using a light with a wavelength of 1.5 times or more of an average particle size of the filler in the resin composition. The use of a light with such a wavelength ensures detection of a mark.

More specifically, when detection is conducted using a light with a wavelength less than 1.5 times of an average particle size of the filler in aligning the mask of the exposure machine with the substrate on which said resin composition is formed or the electronic component on which said resin composition is formed, a probability of collision of the light with the filler causing diffuse reflection is increased, making it difficult to recognize the mark. In contrast, when detection is conducted using a light with a wavelength of 1.5 times or more of an average particle size of the filler, a probability of collision of the light with the filler is reduced, making it easier to recognize the mark.

It, therefore, can facilitate alignment of the mask of the exposure machine with the substrate or the electronic component and thus can improve an efficiency in producing an electronic device.

Furthermore, in the present invention, the resin composition is formed as a film and a content of the filler in the resin composition is preferably 1 wt % or more and 50 wt % or less.

A filler content of 50 wt % or less further ensures detection of a mark.

A filler content of 1 wt % or more can improve shape retention and heat resistance and moisture resistance of the resin composition. Furthermore, strength of the resin composition can be ensured.

It is preferable that a CV of the particle size of the filler in the resin composition is 50% or less.

CV of a particle size=(σ1/Dn1)×100%

wherein σ1 represents a standard deviation of a particle size and Dn1 represents an average particle size.

When a CV of the particle size of the filler in the resin composition is 50% or less, variation in the particle size of the filler is so reduced that a mark can be more reliably detected.

Furthermore, the filler in the resin composition is preferably silica.

Silica contains a less amount of ionic impurities than any other filler, and thus can prevent corrosion of an electronic device, resulting in improved reliability of the electronic device.

In addition, silica having a silanol group exhibits good adhesiveness to a resin component and thus can improve mechanical properties of the resin composition. Thus, heat resistance of the resin composition can be improved.

In aligning the mask of the exposure machine with the substrate on which said resin composition is formed or the electronic component on which said resin composition is formed, a wavelength of the light for detecting the mark is preferably 300 nm or more and 900 nm or less.

The use of a light with a wavelength of 300 nm or more and 900 nm or less for detecting a mark further ensures detection of a mark.

Furthermore, the resin composition contains the above photocurable resin, a photopolymerization initiator, a thermosetting resin and a curing resin cured by both light and heat, and preferably the thermosetting resin is a silicone-modified epoxy resin and the curing resin cured by both light and heat contains a (meth) acryl-modified phenol resin or a (meth)acrylic acid polymer having a (meth)acryloyl group.

The use of such a resin composition makes exposure efficient and improves adhesiveness of a substrate and an electronic component.

When such a resin composition is used, the electronic component and the substrate can be bonded by the resin component. It, therefore, allows a spacer itself for ensuring a gap between the substrate and the electronic component to bond the substrate to the electronic component, so that an adhesion layer need not be formed, resulting in cost saving.

Furthermore, the above substrate is a transparent substrate, and the above electronic component has a light receiving unit and a base substrate on which the light receiving unit is formed, and the electronic device is preferably a light receiving device.

The above electronic component can have a plurality of light receiving units and a base substrate on which the plurality of light receiving units are formed, and after placing the substrate and the electronic component such that they face each other and bonding these via the resin composition, the combination of the electronic component and the transparent substrate can be diced for each light receiving unit.

When a base substrate on which a plurality of light receiving units is formed is used and a combination of the electronic component and the transparent substrate is diced for each light receiving unit, it is essential that the mask in the exposure machine is precisely aligned with the electronic component or the substrate having a resin composition.

It is because that when the mask of the exposure machine is precisely aligned with the electronic component on which said resin composition is formed or the substrate on which said resin composition is formed, a plurality of electronic devices having a resin composition in a predetermined region can be simultaneously produced by dicing.

According to the present invention, there is provided a process for manufacturing an electronic device whereby a production efficiency can be improved.

### BRIEF DESCRIPTION OF THE DRAWINGS

The above objectives and other objectives, features and advantages will be more clearly understood with reference to the preferred embodiments described below and the following accompanied drawings.

FIG. 1 schematically shows a production process for a light receiving device according to an embodiment of the present invention.

FIG. 2 shows a light receiving device.

### BEST MODE FOR CARRYING OUT THE INVENTION

An embodiment of the present invention will be described with reference to the drawings.

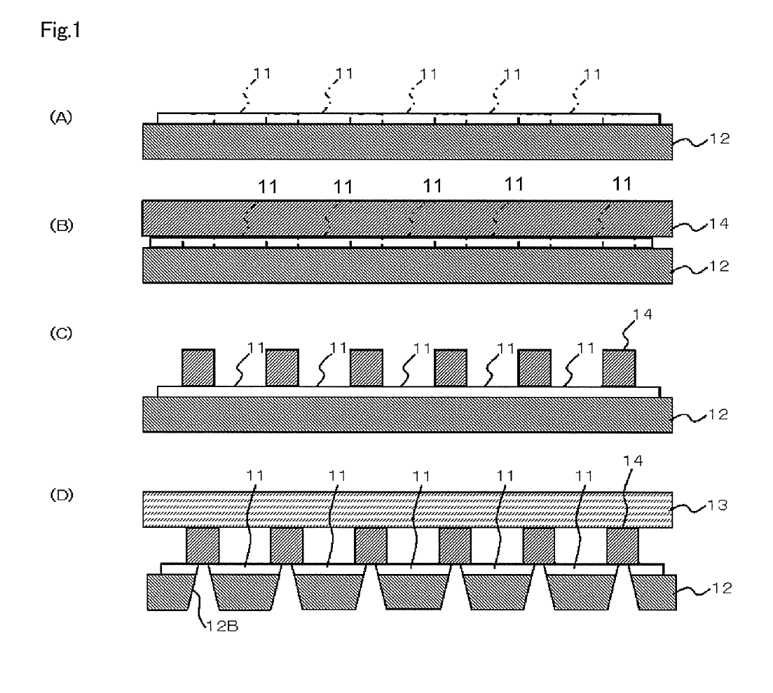

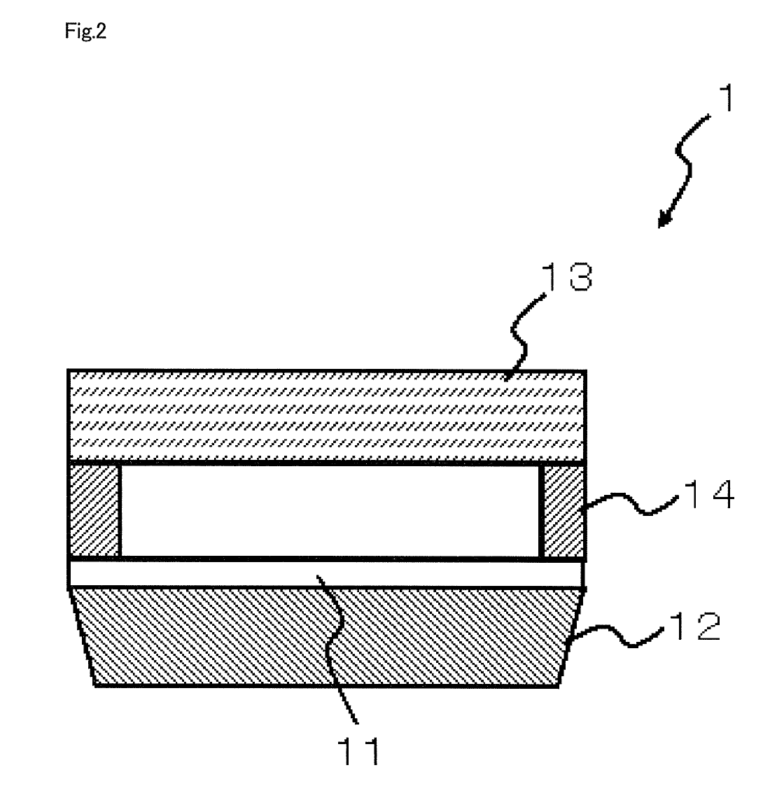

First, a process for manufacturing an electronic device of this embodiment will be generally described with reference to FIGs. 1 and 2.

In this embodiment, the electronic device is a light receiving device 1 such as an imaging device (solid imaging device).

A process for manufacturing a light receiving device 1 of this embodiment contains forming a resin composition containing a filler and a photocurable resin over a substrate (a transparent substrate 13) having a mark or an electronic component (a light receiving unit 11 and a base substrate 12 on which the light receiving unit 11 is formed) having a mark such that the resin composition covers the mark; aligning a mask of an exposure machine with the substrate on which said resin composition is formed or the electronic component on which said resin composition is formed; selectively exposing the resin composition with light via the mask and then the developing the resin composition for leaving the resin composition in a predetermined region; and placing the substrate and the electronic component such that they face each other and bonding these via the resin composition.

In aligning a mask of an exposure machine with the substrate on which said resin composition is formed or the electronic component on which said resin composition is formed, the mark is detected using a light with a wavelength of 1.5 times or more of an average particle size of the filler in the resin composition and the mask of the exposure machine is aligned mask with the substrate on which said resin composition is formed or the electronic component on which said resin composition is formed.

There will be detailed a process for manufacturing an electronic device (a light receiving device 1) of this embodiment.

As shown in FIG. 1(A), abase substrate 12 is prepared, on which a plurality of light receiving units 11 is formed.

The base substrate 12 is, for example, a semiconductor substrate, and a microlens array constituting the plurality of light receiving unit 11 is formed on the base substrate 12. The surface under the microlens array, that is, the base substrate 12, has a photoelectric conversion unit (not shown), where a light received by the light receiving unit 11 is converted into an electric signal.

The base periphery of the substrate 12 protrudes outward from the microlens array. In the base substrate 12, a mark is formed, which is used for alignment with a mask in an exposure machine.

Subsequently, as shown in FIG. 1(B), the resin composition is provided on the base substrate 12 such that the composition covers the microlens array and the mark.

Here, the resin composition may be fainted as a film or a varnish.

In this embodiment, the resin composition is a film (hereinafter, referred to as an “adhesion film”).

The adhesion film 14 has a thickness of, for example, 5 μm or more and 100 μm or less.

This adhesion film 14 contains a filler and a photocurable resin.

Examples of the photocurable resin include ultraviolet curable resins containing an acrylic compound as a main component; ultraviolet curable resins containing an urethane acrylate oligomer or a polyester urethane acrylate oligomer as a main component; and ultraviolet curable resin containing at least one selected from the group consisting of an epoxy resin, a bisphenol resin, a bismaleimide resin and a diallyl phthalate resin as a main component.

Among these, an ultraviolet curable resin containing an acrylic compound as a main component is preferable. Since an acrylic compound is rapidly cured by light irradiation, a resin can be patterned with a relatively small exposure amount.

The acrylic compound can be any compound having a (meth) acryloyl group (a methacryloyl group) including, but not limited to, monofunctional (meth)acrylates having one (meth)acryloyl group, bifunctional (meth)acrylates having two (meth)acryloyl groups and polyfunctional (meth)acrylates having three or more (meth)acryloyl groups; more specifically, bifunctional (meth)acrylates such as ethyleneglycol di(meth)acrylate, 1,6-hexanediol di(meth)acrylate, glycelol di(meth)acrylate and 1,10-decanediol di(meth)acrylate and polyfunctional (meth)acrylates such as trimethylolpropane tri(meth)acrylate, pentaerythritol tri(meth)acrylate and dipentaerythritol hexa(meth)acrylate. The acrylic compound also includes polyalkyleneglycol di(meth)acrylates such as polyethyleneglycol di(meth)acrylate and polypropyleneglycol di(meth)acrylate. The acrylic compound can further include urethane (meth)acrylates and epoxy(meth)acrylates.

Among the acrylic compounds, preferred are bifunctional (meth)acrylates such as triethyleneglycol di(meth)acrylate, 1,6-hexanediol di(meth)acrylate, glycelol di(meth)acrylate and 1,10-decanediol di(meth)acrylate, particularly triethyleneglycol di(meth)acrylate in the light of excellent balance between photocuring reactivity and toughness of a photosensitive adhesive resin composition.

The content of a photocurable resin (an ultraviolet curable resin) is preferably, but not limited to, 5% by weight or more and 60% by weight or less, particularly preferably 8% by weight or more and 30% by weight or less to the total of the resin composition. With the content being less than 5% by weight, the resin composition may not be patterned by ultraviolet irradiation, while with the content being more than 60% by weight, the resin becomes so soft that sheet properties before ultraviolet irradiation may be deteriorated.

Furthermore, the resin composition preferably contains a photopolymerization initiator.

It allows the resin composition to be efficiently patterned by photopolymerization.

Examples of the photopolymerization initiator include benzophenone, acetophenone, benzoin, benzoin isobutyl ether, methyl benzoin benzoate, benzoin benzoic acid, benzoin methyl ether, benzyl phenyl sulfide, benzil, dibenzyl and diacetyl.

The content of the photopolymerization initiator is, but not limited to, preferably 0.5% by weight or more and 5% by weight or less, particularly preferably 0.8% by weight or more and 2.5% by weight or less to the total of the resin composition. With the content being less than 0.5% by weight, photopolymerization may be less effectively initiated, while with the content being more than 5% by weight, the system becomes so reactive that storage stability and/or resolution power may be reduced.

Furthermore, the resin composition contains a thermosetting resin. Examples of the thermosetting resin include novolac type phenol resins such as phenol novolac resins, cresol novolac resins and bisphenol-A novolac resin; phenol resins such as resol phenol resins; bisphenol type epoxy resins such as bisphenol-A epoxy resins and bisphenol-F epoxy resins; novolac type epoxy resins such as phenol novolac epoxy resins, cresol novolac epoxy resins and bisphenol-A novolac epoxys; epoxy resins such as biphenyl type epoxy resins, stilbene type epoxy resins, triphenyl methane type epoxy resins, alkyl-modified triphenyl methane type epoxy resins, triazine-containing epoxy resins and dicyclopentadiene-modified phenol type epoxy resins; triazine-containing resins such as urea resins and melamine resins; unsaturated polyester resins; bismaleimide resins; polyurethane resins; diallyl phthalate resins; silicone resins; benzoxazine-containing resins; and cyanate ester resins, which can be used alone or in combination. Among these, epoxy resins are particularly preferable It can further improve heat resistance and adhesiveness.

Furthermore, the epoxy resin described above is preferably a silicone-modified epoxy resin, and among others it is preferably a combination of an epoxy resin which is solid at room temperature (particularly, a bisphenol type epoxy resin) and an epoxy resin which is liquid at room temperature (particularly, a silicone-modified epoxy resin which is liquid at room temperature). It can provide a resin composition which is excellent in both flexibility and resolution while maintaining heat resistance.

The content of the thermosetting resin is, but not limited to, preferably 10% by weight or more and 40% by weight or less, particularly preferably 15% by weight or more and 35% by weight or less, to the total of the resin composition. With the content being less than 10% by weight, heat resistance may be insufficiently improved, while with the content being more than 40% by weight, toughness of the resin composition may be insufficiently improved.

Furthermore, the resin composition preferably contains a curing resin which is cured by both light and heat. It can improve compatibility of the photocurable resin with the thermosetting resin, resulting in improved strength of the resin composition after curing (photo- and thermo-curing).

Examples of a curing resin which can be cured by both light and heat include thermosetting resins having a photoreactive group such as acryloyl, methacryloyl and vinyl and photocurable resins having a thermally reactive group such as epoxy, phenolic hydroxy, alcoholic hydroxy, carboxyl, acid anhydride, amino and cyanate. Specific examples include (meth) acryl-modified phenol resins, acryl copolymerized resins having a carboxyl and a (meth) acryl groups in a side chain, (meth) acrylic acid polymers containing a (meth)acryloyl group, and epoxy acrylate resins containing a carboxyl group. Among these, (meth) acryl-modified phenol resins are preferable. It allows for the use of an aqueous alkaline solution having little effect on the environment instead of an organic solvent as a developer and maintaining heat resistance.

For the thermosetting resin having a photoreactive group described above, a modification rate (a substitution rate) of the photoreactive group is, but not limited to, preferably 20% or more and 80% or less, particularly preferably 30% or more and 70% or less to the total of reactive groups in the curing resin which is cured by both light and heat (the total of photoreactive and thermally reactive groups). The modification rate within the range of 20% or more and 80% or less can provides particularly excellent resolution.

For the photocurable resin having a thermally reactive group described above, a modification rate (a substitution rate) of the thermally reactive group is, but not limited to, preferably 20% or more and 80% or less, particularly preferably 30% or more and 70% or less, to the total of reactive groups in the curing resin which is cured by both light and heat (the total of photoreactive and thermally reactive groups). The modification rate within the range of 20% or more and 80% or less can provides particularly excellent resolution.

The content of the curing resin which is cured by both light and heat is, but not limited to, preferably 15% by weight or more and 50% by weight or less, particularly preferably 20% by weight or more and 40% by weight or less to the total of the resin composition. With the content being less than 15% by weight, compatibility may be insufficiently improved while with the content being more than 50% by weight, developing properties and resolution may be deteriorated.

The filler can be, for example, silica. The filler preferably, for example, has an average particle size of 0.01 μm or more and 0.4 μm or less.

An average particle size of 0.01 μm or more facilitates handling of the filler. On the other hand, a filler with an average particle size of 0.4 μm or less can eliminate the necessity of a light with a large wavelength for detecting a mark, and thus a generally used wavelength can be employed.

In particular, it is more preferably 0.03 μm or more because both alignment properties and shape stability as a frame material can be achieved. In the light of prevention of filler aggregation, the filler preferably has an average particle size of 0.1 μm or more.

In addition, the filler particularly preferably has an average particle size of 0.3 μm or less. A filler with an average particle size of 0.3 μm or less is effective in satisfactory alignment with a visible light.

An average particle size of the filler can be determined as follows.

A resin composition (after drying when a resin composition as a varnish is used) is observed by a metallographical microscope (transmitted light, observation magnification: 1000, observation area: 0.051156 mm²). A projection image of the filler obtained by the observation is processed using an image processing software to determine a particle number and a particle size, based on which an average particle size (a number average particle size) is calculated.

When there is a particle aggregate (secondary particle), the aggregate is regarded as one particle and its size is determined.

Silica is preferably surface-treated. For example, it is preferably surface-treated with, for example, a silane coupling agent.

The use of such silica is effective in increasing adhesiveness of interface between resin component and silica and thus improving strength of the resin composition.

When a resin composition is prepared, a varnish containing silica is blended with resin components, and the varnish preferably contains a surfactant for improving dispersibility of the silica. The use of such a varnish can prevent the silica from aggregating in the resin composition.

A content of the filler in the adhesion film 14 is preferably 1 wt % or more and 50 wt % or less.

Particularly, it is more preferably 10 wt % or more and 35 wt % or less.

A CV of a particle size of the filler is preferably 50% or less, particularly preferably 40% or less.

A CV is calculated by the following equation.

CV of a particle size=(σ1/Dn1)×100%

wherein σ1 represents a standard deviation of a particle size and Dn1 represents an average particle size.

A standard deviation is calculated by dispersing a filler in water by sonicating for one minute using a laser diffraction type particle size distribution measuring apparatus SALD-7000 and then determining a particle size. A D50 is an average particle size. In Examples and Comparative Examples described later, CVs are calculated according to this method.

The adhesion film 14 can contains additives such as a thermoplastic resin, a leveling agent, an antifoam agent, a coupling agent and an organic peroxide.

The adhesion film 14 can have such a light transmittance to a light applied to a mark that the mark in the base substrate 12 can be detected.

Subsequently, the base substrate 12 with the adhesion film 14 is aligned with the mask of the exposure machine (not shown).

In this alignment step, the mark formed in the base substrate 12 (herein, referred to as an “alignment mark”) is detected by an exposure machine and the mask of the exposure machine is positioned on the basis of the mark.

Specifically, a light is applied to the mark in the base substrate 12 while an image of the mark is taken by an image sensing device such as a CCD camera. Based on the image taken by an image sensing device, the position of the mark is detected and the position of the base substrate 12 in relation to the mask is adjusted.

A wavelength of the light applied to the mark in the base substrate 12 is 1.5 times or more of an average particle size of the filler in the adhesion film 14. Furthermore, it is preferably 2 folds or more and 2.5 times or less. For example, a wavelength of the light applied to the mark in the base substrate 12 is preferably 300 nm or more and 900 nm or less. Particularly, it is preferably 400 nm or more and 800 nm or less.

After the alignment of the base substrate 12 with the exposure machine, the adhesion film 14 is selectively irradiated with a light (ultraviolet rays) from an exposure machine. Thus, the irradiated region in the adhesion film 14 is photocured. When the adhesion film 14 after the exposure is developed by a developer (for example, an alkaline solution, an organic solvent and so on), the irradiated region remains without being dissolved in the developer. The adhesion film 14 is left as a lattice in the region other than each light receiving unit 11 on the base substrate 12 such that it surrounds the light receiving unit 11 (see FIG. 1(C)).

Then, on the adhesion film 14 is placed a transparent substrate 13, then the base substrate 12 is bonded to the transparent substrate 13 via the adhesion film 14. For example, the base substrate 12 and the transparent substrate 13 are heated and pressed to be bonded via the adhesion film 14. A temperature during the heat/press bonding is 80° C. to 180° C.

Here, based on the mark formed in the base substrate 12, the transparent substrate 13 can be placed.

Next, the base substrate 12 and the transparent substrate 13 which have been bonded are divided for each light receiving unit (see FIG. 1(D)). Specifically, the product is cut from the side of the base substrate 12 by a dicing saw to form a trench 12B and the base substrate 12 and the transparent substrate 13 are divided for each light receiving unit 11.

The above process can provide the light receiving device 1 shown in FIG. 2. Specifically, the light receiving device 1 has the base substrate 12 on which the light receiving unit 11 is provided and the transparent substrate 13 facing the base substrate 12, where the frame material (spacer) ensuring a gap between the base substrate 12 and the transparent substrate 13 and surrounding the light receiving unit 11 is placed between the transparent substrate 13 and the base substrate 12. This frame material is the adhesion film 14.

There will be described effects of this embodiment.

In aligning the mask of the exposure machine with the base substrate 12 on which a resin composition (the adhesion film 14) is formed, the mark is detected using a wavelength of 1.5 times of an average particle size of the filler in the adhesion film 14. The use of a light with such a wavelength can ensure detection of the mark.

It, therefore, can facilitate alignment of the mask of the exposure machine with the base substrate 12 and thus can improve an efficiency in producing the light receiving device 1.

Particularly, the mark can be more reliably detected using a light with a wavelength of 2 times or more of an average particle size of the filler in the adhesion film 14.

The filler mainly exists as primary particles in the adhesion film, but some may exist as secondary particles. Therefore, the mark can be reliably detected using a light with a wavelength of 1.5 times or more of an average particle size of the filler.

When, as in this embodiment, a plurality of light receiving units 11 are provided on the base substrate 12 and the combination of the base substrate 12 and the transparent substrate 13 is diced for each light receiving unit 11, it is extremely important to precisely align the mask of the exposure machine with the transparent substrate 13 on which the adhesion film 14 is formed.

It is because precise alignment of the mask of the exposure machine with the transparent substrate 13 allow for simultaneously preparing a number of light receiving devices having the frame-shaped adhesion film 14 in a predetermined position by dicing.

In this embodiment, a content of the filler in the adhesion film 14 is 50 wt % or less, particularly 35 wt % or less, so that the mark can be more reliably detected.

A filler content of 1 wt % or more, particularly 10 wt % or more can improve heat resistance and moisture resistance of the resin composition. In addition, strength of the resin composition can be ensured.

In this embodiment, a CV of a particle size of the filler is 50% or less, particularly preferably 40% or less. It can significantly reduce variation in a particle size of the filler, so that the mark can be more reliably detected.

In this embodiment, silica is used as the filler in the adhesion film 14. The use of silica ensure more reliable detection of the mark.

Silica contains a less amount of ionic impurities than any other filler, and thus can prevent corrosion of a light receiving device, resulting in improved reliability of the light receiving device.

In addition, silica having a silanol group exhibits good adhesiveness to a resin component and thus can improve mechanical properties of a frame material. Thus, heat resistance of the frame material can be improved.

In this embodiment, the resin composition contains a photocurable resin, a photopolymerization initiator, a thermosetting resin and a curing resin cured by both light and heat.

Using such a resin composition, the transparent substrate 13 can be bonded to the base substrate 12 via the resin composition. It, therefore, allows a spacer itself for ensuring a gap between the transparent substrate 13 and the base substrate 12 to bond the transparent substrate 13 to the base substrate 12, so that an adhesion layer in addition to the spacer need not be formed, resulting in cost saving.

When an adhesion layer in addition to a spacer is formed, it may be difficult to detect the mark formed in the base substrate 12. In contrast, in this embodiment where a spacer acts as an adhesive, difficulty in detecting the mark in the base substrate 12 can be eliminated.

The present invention is not limited to the embodiment described above, and variations and modifications are encompassed within the present invention as long as the objectives of the present invention can be achieved.

For example, in the above embodiment, the filler in the resin composition is silica, but without being limited to the embodiment, another filler (for example, zeolite) can be used. Furthermore, the filler may be made of not a single material, but a plurality of different materials.

Furthermore, in the above embodiment, the adhesion film 14 which is a resin composition formed as a film is laminated on the base substrate 12 and the base substrate 12 is bonded to the transparent substrate 13, but without being limited to the embodiment, the adhesion film 14 may be laminated on the transparent substrate 13. In such a case, the mark formed in the transparent substrate 13 is aligned with the mask.

In the above embodiment, the adhesion film 14 is laminated on the base substrate 12, then transparent substrate 13 is bonded via the adhesion film 14, and then the product is diced, but without being limited to the embodiment, the adhesion film 14 can be laminated on the base substrate 12, then the base substrate 12 can be diced for each light receiving unit and then the transparent substrate 13 can be bonded.

In the above embodiment, alignment of the mask of the exposure machine is conducted using the mark exclusively for alignment which is formed in the base substrate 12, but without being limited to the embodiment, a dicing line formed in the base substrate 12 can be used as a mark for alignment.

### EXAMPLES

There will be described Examples of the present invention.

### Example 1

### Synthesis of a Methacryloyl-Modified Novolac Type Bisphenol-A Resin MPN001

500 g of a MEK (methyl ethyl ketone) solution which included a novolac type bisphenol-A resin (Phenolite LF-4871, Dainippon Ink and Chemicals, Incorporated) as a solid content of 60% was charged in a two liter flask and then added 1.5 g of tributylamine as a catalyst and 0.15 g of hydroquinone as a polymerization inhibitor to the flask, and the mixture was heated to 100° C. 180.9 g of glycidyl methacrylate was dripped to the mixture over 30 min, and the mixture was reacted with stirring at 100° C. for 5 hours, a methacryloyl-modified novolac type bisphenol-A resin MPN001 (methacryloyl modification rate: 50%) with a solid content of 74% was produced.

### Preparation of a Resin Composition Varnish

9.8% by weight of triethyleneglycol dimethacrylate (Shin-nakamura Chemical Corporation, trade name: NK ester 3G) as a photocurable resin, 19.8% by weight of a bisphenol-A novolac type epoxy resin (Dainippon Ink and Chemicals, Incorporated, trade name: N865) as a thermosetting resin, 3.6% by weight of silicone-modified epoxy resin (Dow Corning Toray Silicone Co. Ltd., trade name: BY16-115) and 31.8% by weight of a methacryloyl-modified novolac type bisphenol-A resin MPN001 as a resin cured by both light and heat were dissolved MEK (methyl ethyl ketone, Daishin Chemical Co. Ltd.) a resin composition varnish with a solid concentration of 71% was produced.

Next, 33.7% by weight of silica (Nippon Shokubai Co., Ltd., KE-P30, average particle size: 0.28 μm, maximum particle size: 0.9 μm) was dispersed as a filler.

Then, as a photopolymerization initiator, 1.3% by weight of 2,2-dimethoxy-1,2-diphenylethane-1-one (Ciba Specialty Chemicals Inc., Irgacure651) was added and the mixture was stirred by a stirring blade (450 rpm) for one hour to prepare a resin composition varnish. Here, the content of the methacryloyl-modified novolac type bisphenol-A resin MPN001 in the above resin composition varnish is that of a solid.

### Preparation of an Adhesion Film

Then, the resin composition varnish was applied to a transparent PET (film thickness: 25 μm), and dried at 80° C. for 15 min, to form an adhesion layer with a thickness of 50 μm, giving an adhesion film.

### Production Process for a Light Receiving Device

The above adhesion film was laminated on a 8-inch semiconductor wafer on which a light receiving unit (base substrate) (thickness: 300 μm) is provided by using the roll laminator (roll temperature: 60° C., speed: 0.3 m/min, syringe pressure: 2.0 kgf/cm²), giving a 8-inch semiconductor wafer with an adhesion layer on which the light receiving unit is formed. Then, a mask of an exposure machine was aligned with the 8-inch semiconductor wafer with an adhesion layer on which the light receiving unit is formed using a light with a wavelength described in Table 1. Then, the product was irradiated with a light with a wavelength of 365 nm at 700 mJ/cm², and then the transparent PET film was peeled off. Then, it was developed using 2.38% TMAH under the conditions of a developer pressure: 0.3 MPa and time: 90 sec to form a frame material consisting of the adhesion layer with a size of 5 mm×5 mm and a width of 0.6 mm.

Subsequently, the 8-inch semiconductor wafer on which the light receiving unit is formed having the above frame and the 8-inch transparent substrate were set on a substrate bonder (SUSS Microtech AG., SB8e), and the 8-inch semiconductor wafer on which the light receiving unit is formed and the 8-inch transparent substrate were bonded and postcured under the conditions of 150° C. and 90 min. The adhered product of the 8-inch semiconductor wafer on which the light receiving unit is formed and the 8-inch transparent substrate was diced into a predetermined size using a dicing saw to give a light receiving device.

### Example 2

A process was conducted as described in Example 1, except that in the step of preparing a resin composition varnish in Example 1, the following material was used.

Silica was NSS-3N (Tokuyama Corporation, average particle size: 0.125 μm, maximum particle size: 0.35 μm).

### Example 3

A process was conducted as described in Example 2, except that in the step of aligning a mask of an exposure machine with a 8-inch semiconductor wafer with an adhesion layer on which a light receiving unit is formed, the light has a wavelength of 400 nm.

### Example 4

A process was conducted as described in Example 2, except that in the step of aligning a mask of an exposure machine with a 8-inch semiconductor wafer with an adhesion layer on which a light receiving unit is formed, the light has a wavelength of 800 nm.

### Example 5

A process was conducted as described in Example 1, except that in the step of preparing a resin composition varnish in Example 1, the following material was used.

Silica was KE-S30 (Nippon Shokubai Co., Ltd., average particle size: 0.24 μm, maximum particle size: 0.9 μm).

### Example 6

A process was conducted as described in Example 2, except that in the step of preparing a resin composition varnish in Example 2, the following material was used.

A resin cured by both light and heat was an acrylic polymer having a carboxyl group and a methacryloyl group (Daicel Chemical Industries, Ltd., trade name: CYCLMER P ACA200M).

### Example 7

A process was conducted as described in Example 1, except that a content of the resin composition varnish was as described below.

14.5% by weight of triethyleneglycol dimethacrylate (Shin-nakamura Chemical Corporation, trade name: NK ester 3G) as a photocurable resin, 29.3% by weight of a bisphenol-A novolac type epoxy resin (Dainippon Ink and Chemicals, Incorporated, trade name: N865) as a thermosetting resin, 5.4% by weight of silicone-modified epoxy resin (Dow Corning Toray Silicone Co. Ltd., trade name: BY16-115) and 46.9% by weight of a methacryloyl-modified novolac type bisphenol-A resin MPN001 as a resin cured by both light and heat were dissolved in MEK (methyl ethyl ketone, Daishin Chemical Co. Ltd.) to give a resin composition varnish with a solid concentration of 71%.

Next, 2.0% by weight of silica (Tokuyama Corporation, NSS-3N, average particle size: 0.125 μm, maximum particle size: 0.35 μm) was dispersed as a filler.

Then, as a photopolymerization initiator, 1.9% by weight of 2,2-dimethoxy-1,2-diphenylethane-1-one (Ciba Specialty Chemicals Inc., Irgacure651) was added and the mixture was stirred by a stirring blade (450 rpm) for one hour to prepare a resin composition varnish. Here, the content of the methacryloyl-modified novolac type bisphenol-A resin MPN001 in the above resin composition varnish is that of a solid.

### Example 8

A process was conducted as described in Example 1, except that a content of the resin composition varnish was as described below.

7.7% by weight of triethyleneglycol dimethacrylate

(Shin-nakamura Chemical Corporation, trade name: NK ester 3G) as a photocurable resin, 15.6% by weight of a bisphenol-A novolac type epoxy resin (Dainippon Ink and Chemicals, Incorporated, trade name: N865) as a thermosetting resin, 2.9% by weight of silicone-modified epoxy resin (Dow Corning Toray Silicone Co. Ltd., trade name: BY16-115) and 24.8% by weight of a methacryloyl-modified novolac type bisphenol-A resin MPN001 as a resin cured by both light and heat were dissolved in MEK (methyl ethyl ketone, Daishin Chemical Co. Ltd.) to give a resin composition varnish with a solid concentration of 71%.

Next, 48.0% by weight of silica (Tokuyama Corporation, NSS-3N, average particle size: 0.125 μm, maximum particle size: 0.35 μm) was dispersed as a filler.

Then, as a photopolymerization initiator, 1.0% by weight of 2,2-dimethoxy-1,2-diphenylethane-1-one (Ciba Specialty Chemicals Inc., Irgacure651) was added and the mixture was stirred by a stirring blade (450 rpm) for one hour to prepare a resin composition varnish.

### Example 9

As a filler, silica (Admatechs Company Ltd., SO-E2, average particle size: 0.5 μm, maximum particle size: 2.0 μm) was dispersed in 33.7% by weight in a resin composition varnish.

Alignment of a mask of an exposure machine a 8-inch semiconductor wafer with an adhesion layer on which a light receiving unit is formed was conducted using a light with a wavelength (800 nm) described in Table 1, and otherwise, a process was conducted as described in Example 1.

### Example 10

Alignment of a mask of an exposure machine with a 8-inch semiconductor wafer with an adhesion layer on which a light receiving unit is formed was conducted using a light with a wavelength (400 nm) described in Table 1, and otherwise, a process was conducted as described in Example 5.

### Comparative Example 1

As a filler, silica (Admatechs Company Ltd., SO-E2, average particle size: 0.5 μm, maximum particle size: 2.0 μm) was dispersed in 33.7% by weight in a resin composition varnish.

Alignment of a mask of an exposure machine with a 8-inch semiconductor wafer with an adhesion layer on which a light receiving unit is formed was conducted using a light with a wavelength (600 nm) described in Table 1, and otherwise, a process was conducted as described in Example 1.

### Comparative Example 2

Alignment of a mask of an exposure machine with 8-inch semiconductor wafer with an adhesion layer on which a light receiving unit is formed was conducted using a light with a wavelength (400 nm) described in Table 1, and otherwise, a process was conducted as described in Example 1.

An average particle size in Examples 1 to 10 and Comparative Examples 1 and 2 was calculated by dispersing a filler in water by sonicating it for one minute using a laser diffraction type particle size distribution measuring apparatus SALD-7000 and then determining a particle size, and a D50 is an average particle size. Here, it has been confirmed that an average particle size in Examples 1 to 10 and Comparative Examples 1 and 2 is substantially equal to an average particle size (a number average particle size) calculated by observing an adhesion film by a metallographical microscope (transmitted beam, observation magnification: 1000, observation area: 0.051156 mm²) and processing the obtained projection image of the filler using an image processing software. Therefore, a ratio of an alignment wavelength in Examples 1 to 10 and Comparative Examples 1 and 2 in Table 1 to a filler particle size is equal to its ratio to an average particle size obtained from observation of an adhesion film by a metallographical microscope.

Examples 1 to 10 and Comparative Examples 1 and 2 were evaluated as follows.

### Alignment Properties

In the step of aligning a mask of an exposure machine with a 8-inch semiconductor wafer with an adhesion layer on which a light receiving unit is formed, alignment properties were evaluated. The following evaluation criteria were used.

∘∘: Even a periphery of a mark shape is clearly observed.

∘: A mark shape is distinguished, but a periphery is somewhat unclear.

x: A mark cannot be distinguished at all.

### Development Properties

A lattice pattern obtained after development of the light receiving device (a pattern before dicing which is a part to be a frame material) was observed by electron microscopy (×5000) and the presence of a residue was evaluated. The following evaluation criteria were used.

∘: A residue is absent.

x: A residue is observed.

### Shape Retention

Flow of a frame material (collapse degree) when a 8-inch semiconductor wafer on which a light receiving unit is formed and a 8-inch transparent substrate were heat/pressure-bonded was visually evaluated. The following evaluation criteria were used.

∘∘: A dimension of a frame material is not changed between before and after heat/pressure bonding.

∘: A frame material is somewhat flown after heat/pressure bonding and its dimension is somewhat changed, but a shape is not significantly changed.

x: A frame material is considerably flown after heat/pressure bonding and both dimension and shape are significantly changed.

The results are shown in Table 1.

TABLE 1

| | | Starting | | | | | | | |
|---|---|---|---|---|---|---|---|---|---|
| | Resin | material | Ex. 1 | Ex. 2 | Ex. 3 | Ex. 4 | Ex. 5 | Ex. 6 | Ex. 7 |
| Composition | Photocurable | (A-1) | 9.8 | 9.8 | 9.8 | 9.8 | 9.8 | 9.8 | 14.5 |
| | resin (A) | | | | | | | | |
| | Thermosetting | (B-1) | 19.8 | 19.8 | 19.8 | 19.8 | 19.8 | 19.8 | 29.3 |
| | resin (B) | (B-2) | 3.6 | 3.6 | 3.6 | 3.6 | 3.6 | 3.6 | 5.4 |
| | Hardening resin | (C-1) | 31.8 | 31.8 | 31.8 | 31.8 | 31.8 | | 46.9 |
| | curable by both | (C-2) | | | | | | 31.8 | |
| | light and heat (C) | | | | | | | | |
| | Photopolymerization | (D-1) | 1.3 | 1.3 | 1.3 | 1.3 | 1.3 | 1.3 | 1.9 |
| | initiator (D) | | | | | | | | |
| | Filler (E) | (E-1) | 33.7 | | | | | | |
| | | (E-2) | | 33.7 | 33.7 | 33.7 | | 33.7 | 2.0 |
| | | (E-3) | | | | | 33.7 | | |
| | | (E-4) | | | | | | | |
| | Total | | 100 | 100 | 100 | 100 | 100 | 100 | 100 |

| | | | | | | | | |
|---|---|---|---|---|---|---|---|---|
| Evaluation | Alignment wavelength (nm) | 600(2.1) | 600(4.8) | 400(3.2) | 800(6.4) | 600(2.5) | 600(4.8) | 600(4.8) |
| | (number in parenthesis is | | | | | | | |
| | a ratio to an average particle | | | | | | | |
| | size of a filler) | | | | | | | |
| | Filler CV (%) | 14.6 | 39.8 | 39.8 | 39.8 | 25.5 | 39.8 | 39.8 |
| | Alignment properties | ∘ | ∘∘ | ∘ | ∘∘ | ∘ | ∘∘ | ∘∘ |
| | Development | ∘ | ∘ | ∘ | ∘ | ∘ | ∘ | ∘ |
| | properties | | | | | | | |
| | Shape retention | ∘∘ | ∘∘ | ∘∘ | ∘∘ | ∘∘ | ∘∘ | ∘ |

| | | Starting | | | | Comp. | Comp. |
|---|---|---|---|---|---|---|---|
| | Resin | material | Ex. 8 | Ex. 9 | Ex. 10 | Ex. 1 | Ex. 2 |
| Composition | Photocurable | (A-1) | 7.7 | 9.8 | 9.8 | 9.8 | 9.8 |
| | resin (A) | | | | | | |
| | Thermosetting | (B-1) | 15.6 | 19.8 | 19.8 | 19.8 | 19.8 |
| | resin (B) | (B-2) | 2.9 | 3.6 | 3.6 | 3.6 | 3.6 |
| | Hardening resin | (C-1) | 24.8 | 31.8 | 31.8 | 31.8 | 31.8 |
| | curable by both | (C-2) | | | | | |
| | light and heat (C) | | | | | | |
| | Photopolymerization | (D-1) | 1.0 | 1.3 | 1.3 | 1.3 | 1.3 |
| | initiator (D) | | | | | | |
| | Filler (E) | (E-1) | | | | | 33.7 |
| | | (E-2) | 48.0 | | | | |
| | | (E-3) | | | 33.7 | | |
| | | (E-4) | | 33.7 | | 33.7 | |
| | Total | | 100 | 100 | 100 | 100 | 100 |

| | | | | | | |
|---|---|---|---|---|---|---|
| Evaluation | Alignment wavelength (nm) | 600(4.8) | 800(1.6) | 400(1.7) | 600(1.2) | 400(1.4) |
| | (number in parenthesis is | | | | | |
| | a ratio to an average particle | | | | | |
| | size of a filler) | | | | | |
| | Filler CV (%) | 39.8 | 45.5 | 25.5 | 45.5 | 14.6 |
| | Alignment properties | ∘ | ∘ | ∘ | x | x |
| | Development | ∘ | ∘ | ∘ | Not | ∘ |
| | properties | | | | evaluable | |
| | Shape retention | ∘∘ | ∘∘ | ∘∘ | Not | ∘∘ |
| | | | | | evaluable | |

(A-1) Triethyleneglycol dimethacrylate (Shin-nakamura Chemical Corporation, trade name: NK ester 3G)
(B-1) Bisphenol-A novolac type epoxy resin (Dainippon Ink and Chemicals, Incorporated., trade name: N865)
(B-2) Silicone-modified epoxy resin (Dow Corning Toray Silicone Co. Ltd., trade name: BY16-115)
(C-1) Methacryloyl-modified novolac type bisphenol-A resin MPN001
(C-2) Acrylic polymer having a carboxyl group and a methacryloyl group (Daicel Chemical Industries, Ltd., trade name: CYCLMER P ACA200M)
(D-1) Photosensitizing agent (Ciba Specialty Chemicals Inc., 2,2-Dimethoxy-1,2-diphenylethane-1-one, trade name: Irgacure651)
(E-1) Silica (Nippon Shokubai Co., Ltd., trade name: KE-P30, average particle size: 0.28 μm, maximum particle size: 0.9 μm)
(E-2) Silica (Tokuyama Corporation, trade name: NSS-3N, average particle size: 0.125 μm, maximum particle size: 0.35 μm)
(E-3) Silica (Nippon Shokubai Co., Ltd., trade name: KE-S30, average particle size: 0.24 μm, maximum particle size: 0.9 μm)
(E-4) Silica (Admatechs Company Ltd., trade name: SO-E2, average particle size: 0.5 μm, maximam particle size: 2.0 μm)

It is demonstrated that in Examples 1 to 10, alignment properties are satisfactory while in Comparative Examples 1 and 2, a mark cannot be detected and alignment properties are unsatisfactory.

1. A process for manufacturing an electronic device comprising
forming a resin composition containing a filler and a photocurable resin over a substrate having a mark or an electronic component having a mark such that the resin composition covers said mark in said substrate or said mark in said electronic component,
aligning a mask of an exposure machine with said substrate on which said resin composition is formed or said electronic component on which said resin composition is formed,
selectively exposing said resin composition with light via said mask and then the developing the resin composition for leaving said resin composition in a predetermined region and
placing said substrate and said electronic component such that they face each other and bonding these via said resin composition,
wherein in said aligning a mask of an exposure machine with said substrate on which said resin composition is formed or said electronic component on which said resin composition is formed, said mark of the substrate on which said resin composition is formed or the mark of the electronic component on which said resin composition is formed is detected using a light with a wavelength of 1.5 times or more of an average particle size of said filler in said resin composition and the mask of said exposure machine is aligned with said substrate on which said resin composition is formed or said electronic component on which said resin composition is formed.

2. The process for manufacturing an electronic device as claimed in claim 1, wherein said resin composition is formed as a film and a content of said filler in said resin composition is 1 wt % or more and 50 wt % or less.

3. The process for manufacturing an electronic device as claimed in claim 1, wherein, a CV of the particle size of said filler in said resin composition is 50% or less as calculated by the following equation:
CV of a particle size=(σ1/Dn1)×100%
wherein σ1 represents a standard deviation of a particle size and Dn1 represents an average particle size.

4. The process for manufacturing an electronic device as claimed in claim 1, wherein said filler in said resin composition is silica.

5. The process for manufacturing an electronic device as claimed in claim 4, wherein an average particle size of said filler is 0.1 μm or more.

6. The process for manufacturing an electronic device as claimed in claim 1, wherein in said aligning the mask of the exposure machine with the substrate on which said resin composition is formed or the electronic component on which said resin composition is formed, a wavelength of the light for detecting said mark is 300 nm or more and 900 nm or less.

7. The process for manufacturing an electronic device as claimed in claim 1, wherein said resin composition is an adhesion layer, which directly contacts said substrate and said electronic component for ensuring a predetermined gap between said substrate and said electronic component while bonding said substrate to said electronic component.

8. The process for manufacturing an electronic device as claimed in claim 1, wherein said resin composition is an adhesion layer, which directly contacts said substrate and said electronic component for ensuring a predetermined gap between said substrate and said electronic component while bonding said substrate to said electronic component,
said filler is silica having an average particle size of 0.1 μm or more,
a CV of the particle size of said filler in said resin composition is 50% or less as calculated by the following equation:
CV of a particle size=(σ1/Dn1)×100%
wherein σ1 represents a standard deviation of a particle size and Dn1 represents an average particle size.

9. The process for manufacturing an electronic device as claimed in claim 1, wherein said resin composition comprises said photocurable resin, a photopolymerization initiator, a thermosetting resin and a curing resin cured by both light and heat.

10. The process for manufacturing an electronic device as claimed in claim 9, wherein said thermosetting resin is a silicone-modified epoxy resin and said curing resin cured by both light and heat contains a (meth)acryl-modified phenol resin or a (meth)acrylic acid polymer having a (meth)acryloyl group.

11. The process for manufacturing an electronic device as claimed in claim 1, wherein
said substrate is a transparent substrate, and
said electronic component has a light receiving unit and a base substrate on which said light receiving unit is formed, and
said electronic device is a light receiving device.

12. The process for manufacturing an electronic device as claimed in claim 1, wherein
said electronic component has a plurality of light receiving units and a base substrate on which said plurality of light receiving units are formed, and
after said placing said substrate and said electronic component such that they face each other and bonding these via said resin composition, the combination of said electronic component and said transparent substrate is diced for each light receiving unit.
